(19) United States
(12) Patent Application Publication
(10) Pub. No.: US 2019/0338412 A1
(43) Pub. Date: Nov. 7, 2019

(54) MATERIAL DEPOSITION ARRANGEMENT, VACUUM DEPOSITION SYSTEM AND METHOD THEREFOR

(71) Applicant: Applied Materials, Inc., Santa Clara, CA (US)

(72) Inventors: Srinivas SALUGU, Hyderabad, Pin (IN); Stefan BANGERT, Steinau (DE); Stefan KELLER, Mainaschaff (DE)

(21) Appl. No.: 15/544,891

(22) PCT Filed: Jan. 31, 2017
(86) PCT No.: PCT/EP2017/052048

§ 371 Date: Jul. 20, 2017

(51) Int. Cl. C23C 14/54; C23C 14/24

(52) U.S. Cl. CPC C23C 14/543; H01L 51/001; C23C 14/243

(57) ABSTRACT

A material deposition arrangement for depositing a material on a substrate in a vacuum deposition chamber is described. The material deposition arrangement comprises at least one material deposition source having a crucible configured to evaporate the material, a distribution assembly connected to the crucible, wherein the distribution assembly is configured for providing the evaporated material to the substrate, and a valve configured to control a flow of the evaporated material from the crucible to the distribution assembly.

### TECHNICAL FIELD

Embodiments of the present disclosure particularly relate to deposition apparatuses for depositing one or more layers, particularly layers including organic materials therein, on a substrate. In particular, embodiments of the present disclosure relate to material deposition arrangements for depositing evaporated material on a substrate in a vacuum deposition chamber, vacuum deposition systems and methods therefor, particularly for OLED manufacturing.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not involve a back light. Therefore, the energy consumption of OLED displays is considerably less than that of traditional LCD displays. Further, the fact that OLEDs can be manufactured onto flexible substrates results in further applications.

The functionality of an OLED depends on the coating thickness of the organic material. This thickness has to be within a predetermined range. In the production of OLEDs, there are technical challenges with respect to the deposition of evaporated materials in order to achieve high resolution OLED devices

Accordingly, there is a continuing demand for providing improved material deposition arrangements, vacuum deposition systems and methods therefor, deposition rate control systems, evaporators and deposition apparatuses.

### SUMMARY

In light of the above, a material deposition arrangement, a vacuum deposition system and a method for depositing a material on a substrate according to the independent claims are provided. Further aspects, benefits, and features of the present disclosure are apparent from the claims, the description, and the accompanying drawings.

According to an aspect of the present disclosure, a material deposition arrangement for depositing a material on a substrate in a vacuum deposition chamber is provided. The material deposition arrangement includes at least one material deposition source having a crucible configured to evaporate the material, a distribution assembly connected to the crucible, wherein the distribution assembly is configured for providing the evaporated material to the substrate, and a valve configured to control a flow of the evaporated material from the crucible to the distribution assembly.

According to another aspect of the present disclosure, a material deposition arrangement for depositing a material on a substrate in a vacuum deposition chamber is provided including a first deposition source and a second deposition source. The first deposition source includes a first crucible configured to evaporate a first material, a first distribution assembly configured for providing the first evaporated material to the substrate, and a first valve configured to control a flow of the evaporated material from the first crucible to the first distribution assembly. The second deposition source includes a second crucible configured to evaporate a second material, a second distribution assembly configured for providing the second evaporated material to the substrate, and a second valve configured to control a flow of the evaporated material from the second crucible to the second distribution assembly.

According to yet another aspect of the present disclosure, a vacuum deposition system is provided. The vacuum deposition system includes a vacuum deposition chamber, a material deposition arrangement according to any of the embodiments described herein in the vacuum deposition chamber, and a substrate support configured for supporting the substrate during material deposition.

According to a further aspect of the present disclosure, a method for operating a material deposition arrangement configured for depositing a material on a substrate in a vacuum deposition chamber is provided. The method includes evaporating a material to be deposited in a crucible connected to a distribution assembly, and providing the evaporated material from the crucible to the distribution assembly, wherein providing the evaporated material from the crucible to the distribution assembly includes controlling a flow of the evaporated material from the crucible to the at least one distribution assembly.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic cross-sectional side view of a material deposition arrangement according to embodiments described herein;

FIG. 2 shows a schematic cross-sectional side view of a material deposition arrangement according to further embodiments described herein;

FIG. 3A shows a detailed schematic cross-sectional side view of an upper portion of a material deposition arrangement according to embodiments described herein;

FIG. 3B shows a detailed schematic cross-sectional side view of a lower portion of a material deposition arrangement according to embodiments described herein;

FIG. 4 shows a detailed schematic cross-sectional side view of an upper portion of a material deposition arrangement according to further embodiments described herein;

FIG. 5 shows a section of FIG. 4 including a coupling arrangement according to embodiments described herein;

FIG. 6A shows a schematic isometric sectional view of a lower portion of a material deposition arrangement according to embodiments described herein with a valve being in a closed state;

FIG. 6B shows a schematic isometric sectional view of lower portion of a material deposition arrangement according to embodiments described herein with a valve being in an open state;

FIG. 7A shows a schematic side view of a material deposition arrangement according to further embodiments described herein;

FIG. 7B shows a more detailed schematic cross-sectional top view of a material deposition arrangement according to further embodiments described herein as exemplarily shown in FIG. 7A;

FIG. 8 shows a schematic view of vacuum deposition according to embodiments described herein with a valve being in an open state; and

FIG. 9 shows a flow chart illustrating a method for operating a material deposition arrangement according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment can apply to a corresponding part or aspect in another embodiment as well.

Before various embodiments of the present disclosure are described in more detail, some aspects with respect to some terms and expressions used herein are explained.

In the present disclosure, a “material deposition arrangement” is to be understood as an arrangement configured for material deposition on a substrate as described herein. In particular, a “material deposition arrangement” can be understood as an arrangement configured for deposition of organic materials, e.g. for OLED display manufacturing, on large area substrates. For instance, a “large area substrate” can have a main surface with an area of 0.5 m² or larger, particularly of 1 m² or larger. In some embodiments, a large area substrate can be GEN 4.5, which corresponds to about 0.67 m² of substrate (0.73×0.92 m), GEN 5, which corresponds to about 1.4 m² of substrate (1.1 m×1.3 m), GEN 7.5, which corresponds to about 4.29 m² of substrate (1.95 m×2.2 m), GEN 8.5, which corresponds to about 5.7 m² of substrate (2.2 m×2.5 m), or even GEN 10, which corresponds to about 8.7 m² of substrate (2.85 m×3.05 m). Even larger generations such as GEN 11 and GEN 12 and corresponding substrate areas can similarly be implemented.

The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates. According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

In the present disclosure, a “vacuum deposition chamber” is to be understood as a chamber configured for vacuum deposition. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10−4 mbar to about 10−7 mbar, especially in the case that a second component besides the evaporated material is present in the vacuum chamber (such as a gas or the like).

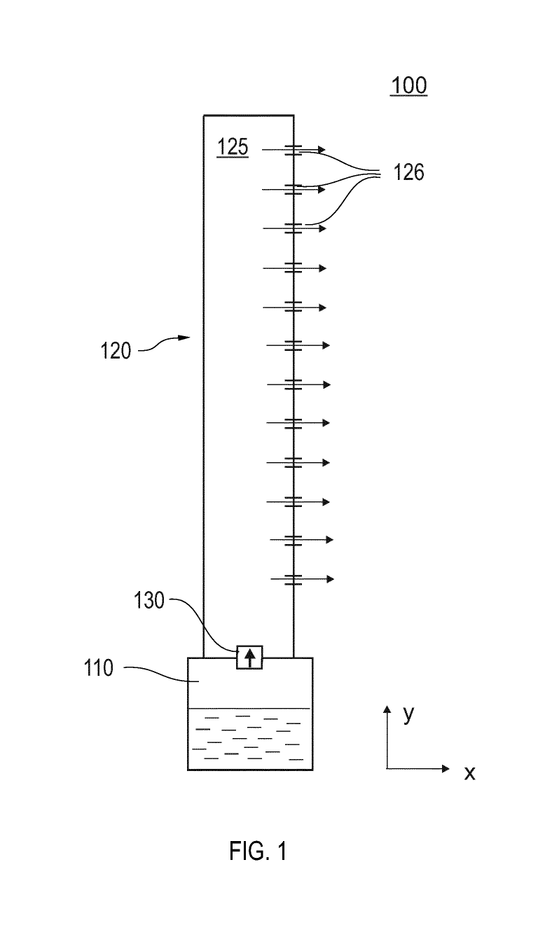

In the present disclosure, a “material deposition source” can be understood as a device or assembly configured for providing a source of material to be deposited on a substrate. In particular, a “material deposition source” may be understood as a device or assembly having a crucible configured to evaporate the material to be deposited and a distribution assembly configured for providing the evaporated material to the substrate. The expression “a distribution assembly configured for providing the evaporated material to the substrate” may be understood in that the distribution assembly is configured for guiding gaseous source material in a deposition direction, exemplarily indicated in FIG. 1 by arrows though the outlets 126. Accordingly, the gaseous source material, for example a material for depositing a thin film of an OLED device, is guided within the distribution assembly and exits the distribution assembly through one or more outlets 126.

In the present disclosure, a “crucible” can be understood as a device having a reservoir for the material to be evaporated by heating the crucible. Accordingly, a “crucible” can be understood as a source material reservoir which can be heated to vaporize the source material into a gas by at least one of evaporation and sublimation of the source material. Typically, the crucible includes a heater to vaporize the source material in the crucible into a gaseous source material. For instance, initially the material to be evaporated can be in the form of a powder. The reservoir can have an inner volume for receiving the source material to be evaporated, e.g. an organic material. For example, the volume of the crucible can be between 100 cm³ and 3000 cm³, particularly between 700 cm³ and 1700 cm³, more particularly 1200 cm³. In particular, the crucible may include a heating unit configured for heating the source material provided in the inner volume of the crucible up to a temperature at which the source material evaporates. For instance, the crucible may be a crucible for evaporating organic materials, e.g. organic materials having an evaporation temperature of about 100° C. to about 600° C.

In the present disclosure, a “distribution assembly” can be understood as an assembly configured for providing evaporated material, particularly a plume of evaporated material, from the distribution assembly to the substrate. For example, the distribution assembly may include a distribution pipe which can be an elongated cube. For instance, a distribution pipe as described herein may provide a line source with a plurality of openings and/or nozzles which are arranged in at least one line along the length of the distribution pipe.

Accordingly, the distribution assembly can be a linear distribution showerhead, for example, having a plurality of openings (or an elongated slit) disposed therein. A showerhead as understood herein can have an enclosure, hollow space, or pipe, in which the evaporated material can be provided or guided, for example from the evaporation crucible to the substrate. According to embodiments which can be combined with any other embodiments described herein, the length of the distribution pipe may correspond at least to the height of the substrate to be deposited. In particular, the length of the distribution pipe may be longer than the height of the substrate to be deposited, at least by 10% or even 20%. For example, the length of the distribution pipe can be 1.3 m or above, for example 2.5 m or above. Accordingly, a uniform deposition at the upper end of the substrate and/or the lower end of the substrate can be provided. According to an alternative configuration, the distribution assembly may include one or more point sources which can be arranged along a vertical axis.

Accordingly, a “distribution assembly” as described herein may be configured to provide a line source extending essentially vertically. In the present disclosure, the term “essentially vertically” is understood particularly when referring to the substrate orientation, to allow for a deviation from the vertical direction of 10° or below. This deviation can be provided because a substrate support with some deviation from the vertical orientation might result in a more stable substrate position. Yet, the substrate orientation during deposition of the organic material is considered essentially vertical, which is considered different from the horizontal substrate orientation. Accordingly, the surface of the substrates can be coated by a line source extending in one direction corresponding to one substrate dimension and a translational movement along the other direction corresponding to the other substrate dimension.

In the present disclosure, a “valve configured to control a flow of the evaporated material” is to be understood as valve which is controllable such that a flow of evaporated material from a crucible as described herein to a distribution assembly as described herein can be controlled. In particular, the valve as described herein can be configured to provide a closed state (e.g. in order to stop a flow of evaporated material from the crucible to the distribution assembly) and an open state (e.g. in order to provide a flow of evaporated material from the crucible to the distribution assembly). For instance, the valve can be configured as a switch which opens and closes a through-hole, e.g. an opening 135 of the valve as described herein, which is open in both directions. Alternatively, the valve can be configured as a switch which opens a through-hole, e.g. an opening 135 of the valve as described herein, in one direction (e.g. from the crucible to the distribution assembly) but is closed in the other direction (e.g. from the distribution assembly to the crucible). Further, the valve as described herein can be configured to control a material flow rate from the crucible to the distribution assembly

FIG. 1 shows a schematic sectional view of a material deposition arrangement 100 according to embodiments described herein. In particular, the material deposition arrangement is configured for depositing a material on a substrate in a vacuum deposition chamber. As exemplarily shown in FIG. 1, the material deposition arrangement includes at least one material deposition source having a crucible 110 configured to evaporate the material. Further, the material deposition arrangement includes a distribution assembly 120 configured for providing the evaporated material to the substrate. Typically, the distribution assembly 120 is connected to the crucible 110. For instance, the distribution assembly can be directly connected to the crucible. Particularly, the distribution assembly and the crucible may have at least one contact surface at which the distribution assembly is in contact with the crucible. For instance a bottom portion of the distribution assembly can be in contact with a top portion of the crucible. As exemplarily shown in FIG. 1, the distribution assembly 120 of the at least one deposition source may include a distribution pipe with one or more outlets 126 provided along the length of the distribution pipe.

As exemplarily shown in FIG. 1, according to embodiments which can be combined with any other embodiments described herein, the material deposition arrangement has a valve 130 configured to control a flow of the evaporated material from the crucible 110 to the distribution assembly 120. In particular, the valve 130 can be provided at a bottom, particularly a bottom wall 121, of the distribution assembly 120. Accordingly, the valve 130 may be configured to close an opening 135 provided at the bottom of the distribution assembly 120. For instance, the opening 135 provided at the bottom of the distribution assembly 120 can be arranged and configured to allow fluid communication with the crucible, for instance via an opening provided in a top wall of the crucible. Alternatively, the valve 130 may be configured to close an opening provided in the crucible, particularly in a top wall of the crucible. Typically, the crucible and the distribution assembly are configured to be connectable to each other such that fluid communication between the crucible and the distribution assembly is confined to the area of the respective openings, e.g. a connection of the opening 135 provided at the bottom of the distribution assembly 120 with the opening provided in a top wall of the crucible.

Accordingly, beneficially a material deposition arrangement is provided in which a flow of evaporated material from the crucible to the distribution assembly of at least one material deposition source can be controlled. Providing a material deposition arrangement with the capability to control the flow of evaporated material from the crucible to the distribution assembly can in particular be beneficial during the start of the deposition process, for instance for adjusting a preselected deposition rate in an initial test deposition process. Further, in the case that the at least one material deposition source includes two or more deposition sources, a deposition rate of each individual deposition source can be independently adjusted and checked by controlling the flow of evaporated material from the respective crucible to the respective distribution assembly. Thus, embodiments of the material deposition arrangement as described herein are configured to reduce the cost of ownership, since wastage of source material, particularly expensive organic material, can be reduced, e.g. during adjustment of the preselected deposition rate or during maintenance.

For instance, for maintenance of a material deposition arrangement according to embodiments described herein, a flow of evaporated material from the crucible to the distribution assembly can be stopped very efficiently in a short period of time. In contrast, in conventional material deposition systems, evaporated material continues to pass the nozzles of the distribution assembly as long as the crucible continues to evaporate the material to be deposited. In this regard it should be noted that starting and stopping evaporation is a slow process because of the heat capacity of the material to be evaporated. Accordingly, providing a material deposition arrangement with a valve as described herein can be beneficial for improving the controllability over the deposition process.

With exemplary reference to FIG. 2, according to embodiments which can be combined with any other embodiment described herein, the valve 130 includes a shutter 131 connected to an actuator arrangement 140. For instance, the shutter 131 can be configured to close an opening 135 provided in the bottom wall 121 of the distribution assembly 120. The actuator arrangement 140 can be configured for actuating the shutter 131. As exemplarily shown in FIG. 2, the actuator arrangement 140 may at least partially be arranged in an interior space 125 of the distribution assembly 120. Typically, the interior space 125 of the distribution assembly 120 is configured for receiving the evaporated material from the crucible 110.

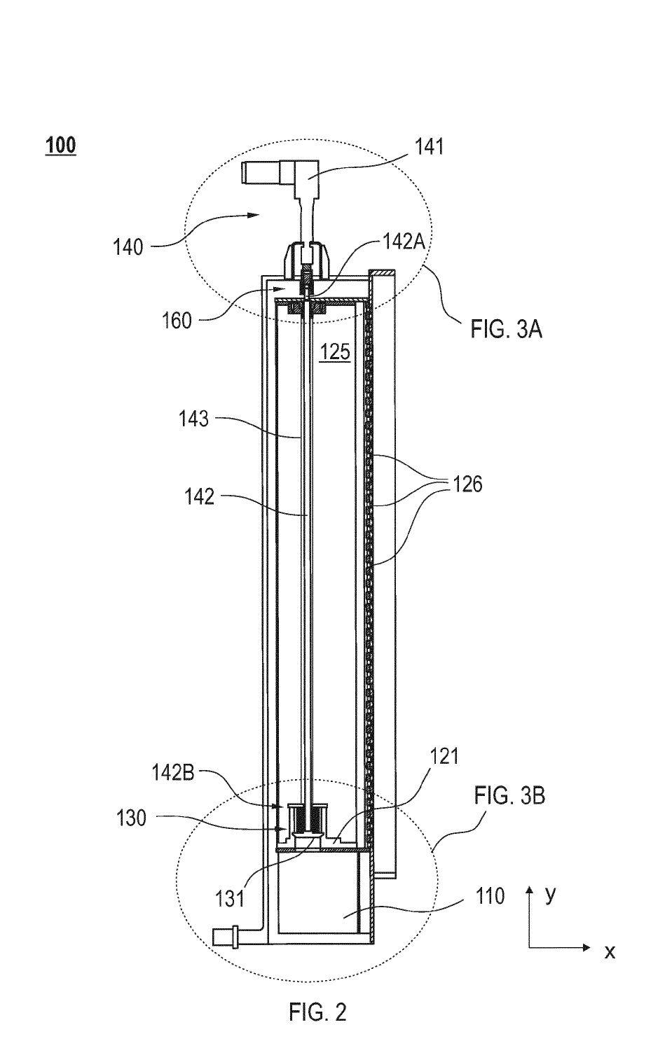

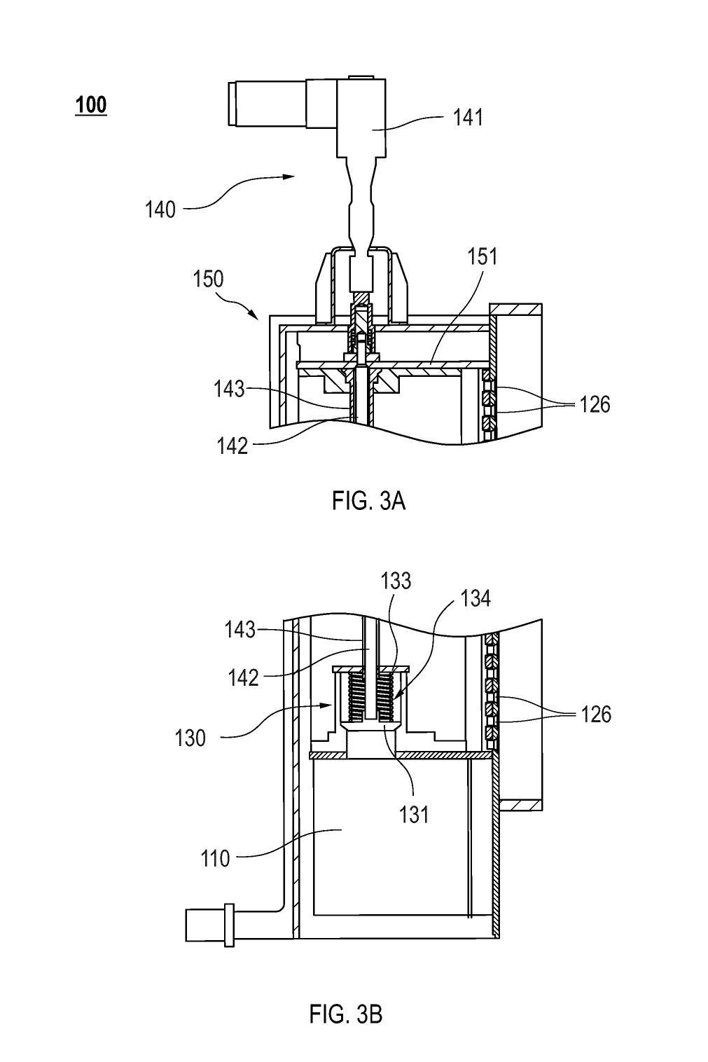

As exemplarily shown in FIGS. 2, 3A and 3B, according to embodiments which can be combined with any other embodiment described herein, the actuator arrangement 140 includes an actuator 141 and a movable element 142. As exemplarily shown in FIGS. 2, 3A and 3B, a first end 142A of the movable element 142 can be connected to the actuator 141 and a second end 142B of the movable element 142 can be connected to the shutter 131. Further, with exemplary reference to FIG. 2, the movable element 142 may be configured to extend through the interior space 125 of the distribution assembly 120.

With exemplary reference to FIG. 2, according to embodiments which can be combined with any other embodiment described herein, the movable element 142 of the actuator arrangement 140 can be an elongated element. In particular, the movable element 142 can be a rod. As exemplarily shown in FIGS. 2, 3A and 3B, the movable element 142 may be provided inside a tube 143. For instance, the elongated element may extend through the interior space 125 of the distribution assembly from at least the valve casing 133 to at least an upper wall 151 of the interior space 125 of the distribution assembly 120. Accordingly, the tube 143 may extend from a valve casing 133 to an upper wall 151 of the interior space 125 of the distribution assembly 120, as exemplarily shown in FIGS. 3A and 3B. For instance, the movable element 142 and/or the tube 143 can be made of titanium.

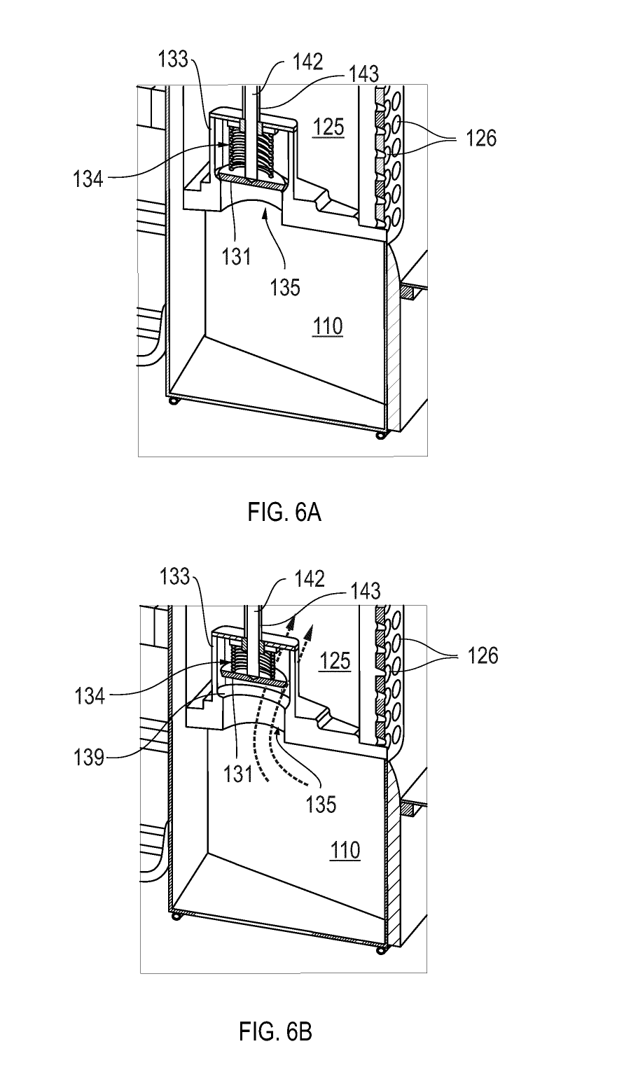

With exemplarily reference to FIGS. 3B, 6A and 6B, according to embodiments which can be combined with any other embodiment described herein, the valve may include a bellow 134 surrounding the second end 142B of the movable element 142. Typically, the bellow 134 is configured to prevent evaporated material from entering the actuator arrangement 140. For instance, as exemplarily shown in FIG. 6B, the bellow can be configured to be deformable.

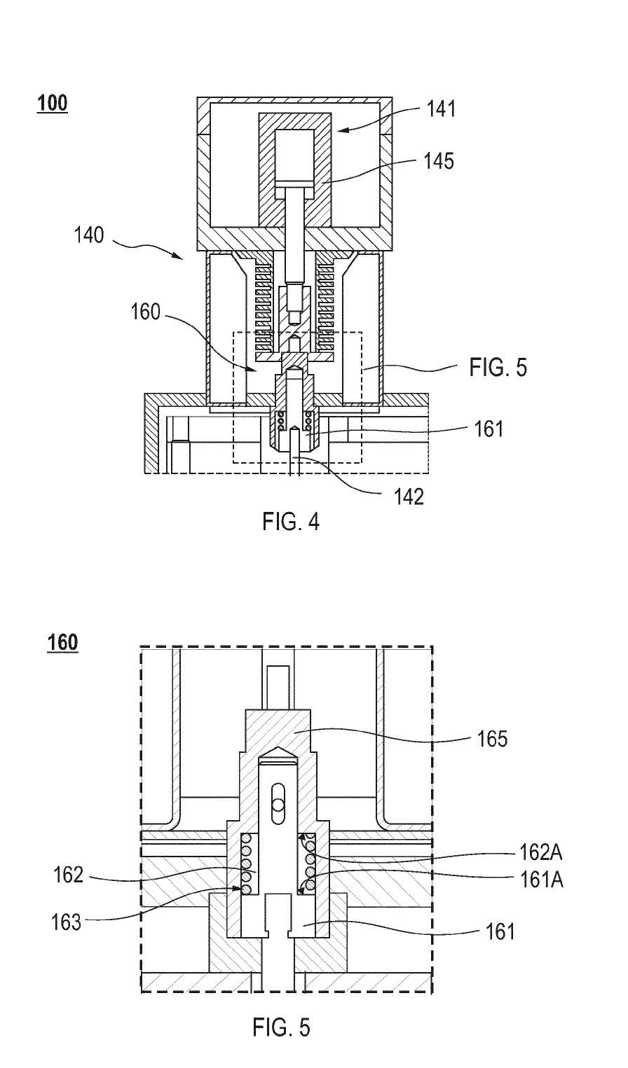

According to embodiments which can be combined with any other embodiment described herein, the movable element 142 may be coupled to the actuator via a coupling arrangement 160, as exemplarily shown in FIGS. 4 and 5. In particular, the coupling arrangement 160 may include a thermal insulation element 161. For instance, the thermal insulation element 161 can be made of zirconium oxide. Providing a thermal insulation element 161 can be beneficial to reduce the heat conduction from the movable element to the actuator, such that the functionality of the actuator can be ensured.

As exemplarily shown in FIG. 5, the coupling arrangement 160 may include a spring 163 provided inside a reception 162 of a coupling element 165. Accordingly, the coupling element 165 can have a reception 162 configured for receiving the thermal insulation element 161. In particular, as shown in FIG. 5, typically the spring 163 is arranged between a first abutment surface 162A of the reception 162 and a second abutment surface 161A of the thermal insulation element 161. Providing a spring can be beneficial for applying a constant pressure of the shutter 131 at a valve seat 139. The valve seat 139 is exemplarily indicated in FIG. 6B. Further, providing a spring can be beneficial to accommodate positional variations of the actuator arrangement, particularly the movable element 142

FIG. 6A shows a schematic isometric sectional view of a lower portion of a material deposition arrangement 100 according to embodiments described herein with the valve 130 shown in a closed state. In FIG. 6B, the valve is shown in an open state. For illustration purposes, a flow of evaporated material, e.g. gaseous organic material, from the crucible 110 to the interior space 125 of the distribution assembly 120 is exemplarily indicated by dotted arrows. Further, as can be seen from a comparison of FIG. 6A and FIG. 6B, the bellow 134 can be configured to be deformable. The bellow can be a metal bellow. For instance, the bellow can be made of stainless steel.

According to embodiments which can be combined with any other embodiment described herein, the one or more outlets of the distribution pipe are nozzles extending along an evaporation direction. Typically, the evaporation direction is essentially horizontal, e.g. the horizontal direction may correspond to the x-direction indicated in FIGS. 1 and 2.

According to embodiments which can be combined with any other embodiment described herein, the actuator 141 can be connected to an exterior surface of a housing 150 of the distribution assembly 120, as exemplarily shown in FIG. 3A. For example, the actuator 141 can be an electrical actuator, a pneumatic actuator 145, as exemplarily shown in FIG. 4, or any other suitable actuator. An electrical actuator may have the advantage that the electrical actuator provides for self-locking at end-positions. A pneumatic actuator, i.e. an actuator having a pneumatic cylinder, as exemplarily shown in FIG. 4, may have the advantage to be more cost-effective.

According to embodiments which can be combined with any other embodiment described herein, the actuator 141 may be configured to provide an axial force of 100N. Further, the actuator 141 may be configured to provide a travel distance of approximately a half of a diameter of the valve, particularly approximately a half of a diameter of the shutter of the valve, or approximately a half of the diameter of the opening 135 of the valve. For example, the diameter D of the valve, particularly the diameter D of the shutter and/or the diameter of the opening 135 of the valve, can be selected from a range having a lower limit of D=10 mm, particularly a lower limit of D=5 mm, more particularly a lower limit of D=20, and an upper limit of D=30 mm, particularly an upper limit of D=40 mm, more particularly an upper limit of D=50 mm. For instance, the diameter D of the valve, particularly the diameter D of the shutter, can be D=26 mm.

According to embodiments which can be combined with any other embodiment described herein, the diameter D of the valve and the travel distance of the actuator (also referred to as stroke of the actuator) are adjusted to a fluid conductance of the evaporated material in the deposition source. For instance, the stroke of the actuator may be adjusted to be approximately half of the diameter of the valve, particularly to be approximately half of a diameter of the shutter of the valve, or to be approximately half of the diameter of the opening 135 of the valve. Accordingly, beneficially a flow of evaporated material in the deposition source, particularly the flow of the evaporated material from the crucible to the distribution assembly can be optimized, e.g. a reduction of flow can be avoided.

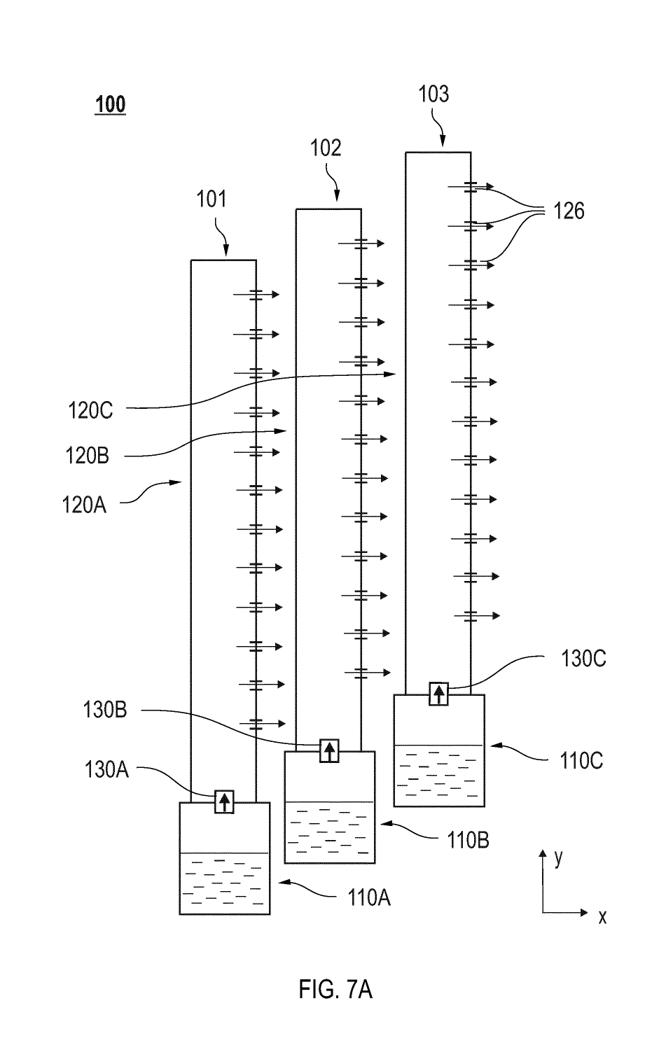

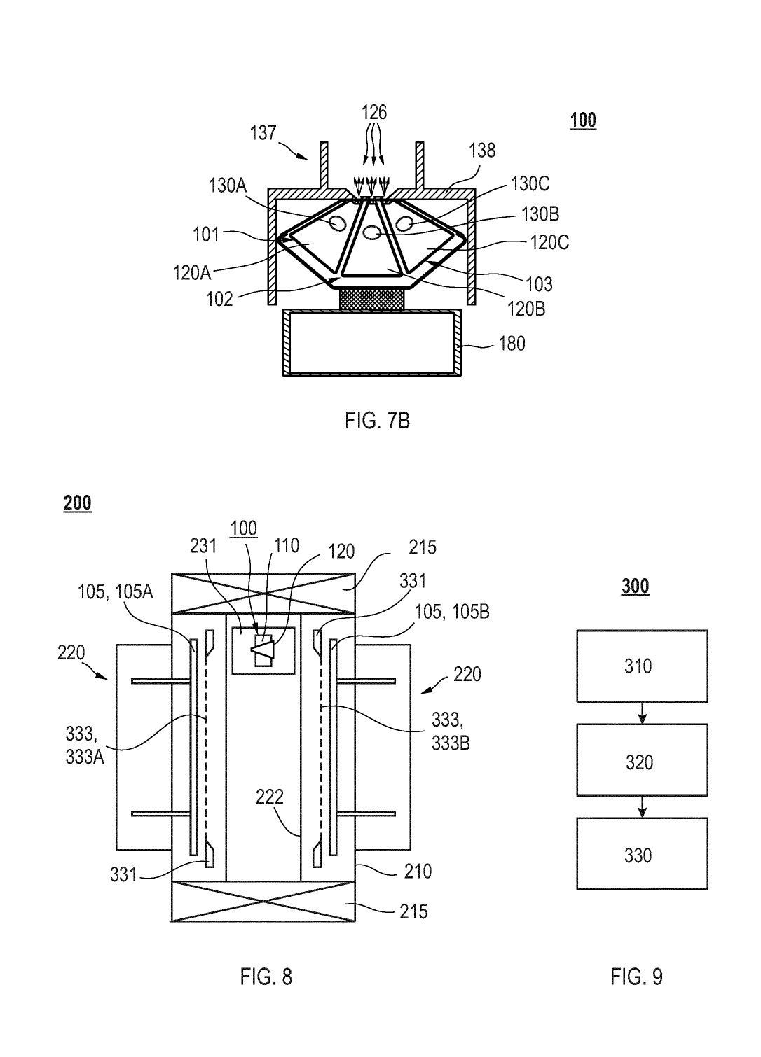

According to embodiments which can be combined with other embodiments described herein, the at least one material deposition source may include a first deposition source 101 and a second deposition source 102. Additionally, a third deposition source 103 may be provided, as exemplarily shown in FIG. 7A. The first deposition source 101 includes a first crucible 110A configured to evaporate a first material, a first distribution assembly 120A configured for providing the first evaporated material to the substrate, and a first valve 130A configured to control a flow of the evaporated material from the first crucible 110A to the first distribution assembly 120A. The second deposition source 102 includes a second crucible 110B configured to evaporate a second material, a second distribution assembly 120B configured for providing the second evaporated material to the substrate, and a second valve 130B configured to control a flow of the evaporated material from the second crucible 110B to the second distribution assembly 120B. The third deposition source 103 includes a third crucible 110C configured to evaporate a third material, a third distribution assembly 120C configured for providing the third evaporated material to the substrate, and a third valve 130C configured to control a flow of the evaporated material from the third crucible 110C to the third distribution assembly 120C.

FIG. 7B shows a more detailed schematic cross-sectional top view of a material deposition arrangement according to further embodiments described herein as exemplarily shown in FIG. 7A. In particular, FIG. 7B shows a cross-sectional top view of a material deposition arrangement including a first deposition source 101, a second deposition source 102, and a third deposition source.

Accordingly, from FIGS. 7A and 7B, it is to be understood that three distribution assemblies, e.g. distribution pipes, and corresponding evaporation crucibles can be provided next to each other. Accordingly, a material deposition arrangement may be provided as an evaporation source array, e.g. wherein more than one kind of material can be evaporated at the same time. Further, an evaporation source array having three distribution assemblies and corresponding evaporation crucibles configured for evaporating organic material may also be referred to as a triple organic source.

In particular, with exemplary reference to FIG. 7B, the at least one material deposition source of the material deposition arrangement 100 may include three deposition sources, e.g. a first deposition source 101, a second deposition source 102, and a third deposition source 103. Typically, each deposition source includes a distribution assembly as described herein, a crucible as described herein, and a valve configured to control a flow of evaporated material from the crucible to the respective distribution assembly as described herein. For instance, the first distribution assembly 120A, the second distribution assembly 120B, and the third distribution assembly 120C can be configured as a distribution pipe as described herein.

In particular, according to embodiments which can be combined with any other embodiments described herein, the distribution assembly of the at least one deposition source can be configured as a distribution pipe having a noncircular cross-section perpendicular to the length of the distribution pipe. For example, the cross-section perpendicular to the length of the distribution pipe can be triangular with rounded corners and/or cut-off corners as a triangle. For instance, FIG. 7B shows three distribution pipes having a substantially triangular cross-section perpendicular to the length of the distribution pipes. According to embodiments which can be combined with any other embodiment described herein, each distribution assembly is in fluid communication with the respective evaporation crucible.

According to embodiments which can be combined with any other embodiment described herein, an evaporator control housing 180 may be provided adjacent to the least one material deposition source, e.g. having a first distribution assembly 120A, a second distribution assembly 120B, and a third distribution assembly 120C, as exemplarily shown in FIG. 7B. In particular, the evaporator control housing can be configured to maintain atmospheric pressure therein and is configured to house at least one element selected from the group consisting of: a switch, a valve, a controller, a cooling unit, a cooling control unit, a heating control unit, a power supply, and a measurement device.

According embodiments which can be combined with any other embodiment described herein, the distribution assembly, particularly the distribution pipe, may be heated by heating elements which are provided inside the distribution assembly. The heating elements can be electrical heaters which can be provided by heating wires, e.g. coated heating wires, which are clamped or otherwise fixed to the inner tubes. With exemplary reference to FIG. 7B, a cooling shield 138 can be provided. The cooling shield 138 may include sidewalls which are arranged such that a U-shaped cooling shield is provided in order to reduce the heat radiation towards the deposition area, i.e. a substrate and/or a mask. For example, the cooling shield can be provided as metal plates having conduits for cooling fluid, such as water, attached thereto or provided therein. Additionally, or alternatively, thermoelectric cooling devices or other cooling devices can be provided to cool the cooled shields. Typically, the outer shields, i.e. the outermost shields surrounding the inner hollow space of a distribution pipe, can be cooled.

In FIG. 7B, for illustrative purposes, evaporated source material exiting the outlets of the distribution assemblies are indicated by arrows. Due to the essentially triangular shape of the distribution assemblies, the evaporation cones originating from the three distribution assemblies are in close proximity to each other, such that mixing of the source material from the different distribution assemblies can be improved. In particular, the shape of the cross-section of the distribution pipes allow to place the outlets or nozzles of neighboring distribution pipes close to each other. According to some embodiments, which can be combined with other embodiments described herein, a first outlet or nozzle of the first distribution assemblies and a second outlet or nozzle of the second distribution assemblies can have a distance of 50 mm or below, e.g. 30 mm or below, or 25 mm or below, such as from 5 mm to 25 mm. More specifically, the distance of the first outlet or nozzle to a second outlet or nozzle can be 10 mm or below.

As further shown in FIG. 7B, a shielding device, particularly a shaper shielding device 137, can be provided, for example, attached to the cooling shield 138 or as a part of the cooling shield. By providing shaper shields, the direction of the vapor exiting the distribution pipe or pipes through the outlets can be controlled, i.e. the angle of the vapor emission can be reduced. According to some embodiments, at least a portion of evaporated material provided through the outlets or nozzles is blocked by the shaper shield. Accordingly, the width of the emission angle can be controlled.

According to another aspect of the present disclosure, a vacuum deposition system 200 is provided, as exemplarily shown in FIG. 8. The vacuum deposition system includes a vacuum deposition chamber 210, a material deposition arrangement 100 according to any of the embodiments described herein in the vacuum deposition chamber 210, and a substrate support 220 configured for supporting a substrate 105 during material deposition.

In particular, the material deposition arrangement 100 can be provided on a track or linear guide 222, as exemplarily shown in FIG. 8. The linear guide 222 may be configured for the translational movement of the material deposition arrangement 100. Further, a drive for providing a translational movement of material deposition arrangement 100 can be provided. In particular, a transportation apparatus for contactless transportation of the material deposition arrangement source may be provided in the vacuum deposition chamber. As exemplarily shown in FIG. 8, the vacuum deposition chamber 210 may have gate valves 215 via which the vacuum deposition chamber can be connected to an adjacent routing module or an adjacent service module. Typically, the routing module is configured to transport the substrate to a further vacuum deposition system for further processing and the service module is configured for maintenance of the material deposition arrangement. In particular, the gate valves allow for a vacuum seal to an adjacent vacuum chamber, e.g. of the adjacent routing module or the adjacent service module, and can be opened and closed for moving a substrate and/or a mask into or out of the vacuum deposition system 200.

With exemplary reference to FIG. 8, according to embodiments which can be combined with any other embodiment described herein, two substrates, e.g. a first substrate 105A and a second substrate 105B can be supported on respective transportation tracks within the vacuum deposition chamber 210. Further, two tracks for providing masks 333 thereon can be provided. In particular, the tracks for transportation of a substrate carrier and/or a mask carrier may be provided with a further transportation apparatus for contactless transportation of the carriers.

Typically, coating of the substrates may include masking the substrates by respective masks, e.g. by an edge exclusion mask or by a shadow mask. According to typical embodiments, the masks, e.g. a first mask 333A corresponding to a first substrate 105A and a second mask 333B corresponding to a second substrate 105B, are provided in a mask frame 331 to hold the respective mask in a predetermined position, as exemplarily shown in FIG. 8.

As shown in FIG. 8, the linear guide 522 provides a direction of the translational movement of the material deposition arrangement 100. On both sides of the material deposition arrangement 100, a mask 333, e.g. a first mask 333A for masking a first substrate 105A and second mask 333B for masking a second substrate 105B can be provided. The masks can extend essentially parallel to the direction of the translational movement of the material deposition arrangement 100. Further, the substrates at the opposing sides of the evaporation source can also extend essentially parallel to the direction of the translational movement.

With exemplary reference to FIG. 8, a source support 231 configured for the translational movement of the material deposition arrangement 100 along the linear guide 222 may be provided. Typically, the source support 231 supports a crucible 110 and a distribution assembly 120 provided over the evaporation crucible, as schematically shown in FIG. 8. Accordingly, the vapor generated in the evaporation crucible can move upwardly and out of the one or more outlets of the distribution assembly. Accordingly, as described herein, the distribution assembly is configured for providing evaporated material, particularly a plume of evaporated organic material, from the distribution assembly 120 to the substrate 105. It is to be understood that FIG. 8 only shows a schematic representation of the material deposition arrangement 100, and that the material deposition arrangement 100 provided in the vacuum deposition chamber 210 of the vacuum deposition system 200 can have any configuration of the embodiments described herein, as exemplarily described with reference to FIGS. 1 to 7B.

According to a further aspect of the present disclosure, a method 300 for operating a material deposition arrangement configured for depositing a material on a substrate in a vacuum deposition chamber is provided. The method can include employing (see block 310) a material deposition arrangement 100 having at least one deposition source including a distribution assembly, a crucible 110, a distribution assembly 120, and a valve 130 configured to control a flow of evaporated material from the crucible 110 to the distribution assembly 120. The method includes evaporating (see block 320) a material to be deposited in a crucible 110 connected to a distribution assembly 120. Additionally, the method includes providing (see block 330) the evaporated material from the crucible 110 to the distribution assembly 120, wherein providing the evaporated material from the crucible 110 to the distribution assembly 120 comprises controlling a flow of the evaporated material from the crucible to the at least one distribution assembly.

In particular, providing the evaporated material from the crucible 110 to the distribution assembly 120 may include guiding the evaporated material through the valve 130. More specifically, guiding the evaporated material through the valve 130 may include controlling a flow of evaporated material from the crucible 110 to the distribution assembly 120. For instance, controlling the flow of evaporated material from the crucible 110 to the distribution assembly 120 typically includes controlling the amount of evaporated material provided from the crucible to a distribution assembly, e.g. a distribution assembly of the first deposition source, a distribution assembly of the second deposition source and/or a distribution assembly of the third deposition source.

According to embodiments which can be combined with any other embodiments described herein, the method may include employing a material deposition arrangement 100 according to any of the embodiments described herein.

Thus, in view of the embodiments described herein, it is to be understood that an improved material deposition arrangement, an improved vacuum deposition system and an improved method for operating a material deposition arrangement is provided, particularly for OLED manufacturing. In particular, an introduction of a valve as described herein into a deposition source, specifically in the evaporative path, e.g. between the crucible and the distribution assembly provides for the possibility to control the flow of evaporated material from the crucible to the distribution assembly. This can in particular be beneficial during the start of the deposition process, for instance for adjusting a preselected deposition rate in an initial test deposition process.

Further, in the case that the at least one material deposition source includes two or more deposition sources, a deposition rate of each individual deposition source can be independently adjusted and checked by controlling the flow of evaporated material from the respective crucible to the respective distribution assembly. Thus, embodiments of the material deposition arrangement as described herein are configured to reduce the cost of ownership, since wastage of source material, particularly expensive organic material, can be reduced, e.g. during adjustment of the preselected deposition rate or during maintenance. In contrast, conventional deposition systems are not capable of shutting off a material flow from a crucible to a distribution assembly. In particular, in conventional systems evaporated organic material will continue to pass to the outlets of a distribution assembly as long as the crucible is evaporating.

While the foregoing is directed to embodiments of the disclosure, other and further embodiments of the disclosure may be devised without departing from the basic scope thereof, and the scope thereof is determined by the claims that follow.

In particular, this written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. A material deposition arrangement for depositing a material on a substrate in a vacuum deposition chamber, comprising:
at least one material deposition source having:
a crucible configured to evaporate the material; and
a distribution assembly connected to the crucible, wherein the distribution assembly is configured for providing the evaporated material to the substrate; and
a valve configured to control a flow of the evaporated material from the crucible to the distribution assembly.

2. The material deposition arrangement according to claim 1, wherein the valve comprises a shutter connected to an actuator arrangement, wherein the actuator arrangement is at least partially arranged in an interior space of the distribution assembly.

3. The material deposition arrangement according to claim 2, wherein the actuator arrangement comprises an actuator and a movable element, wherein the movable element extends through the interior space of the distribution assembly.

4. The material deposition arrangement according to claim 3, wherein the movable element is an elongated element extending from at least a valve casing to at least an upper wall of the interior space of the distribution assembly.

5. The material deposition arrangement according to claim 3, wherein the valve comprises a bellows configured to prevent evaporated material from entering the actuator arrangement.

6. The material deposition arrangement according to claim 3, wherein the movable element is coupled to the actuator via a coupling arrangement comprising a thermal insulation element.

7. The material deposition arrangement according to claim 6, wherein the coupling arrangement comprises a spring provided inside a reception of a coupling element.

8. The material deposition arrangement according to claim 1, wherein the distribution assembly comprises a distribution pipe with one or more outlets provided along the length of the distribution pipe.

9. The material deposition arrangement according to claim 8, wherein the one or more outlets are nozzles extending along an evaporation direction, and wherein the evaporation direction is essentially horizontal.

10. The material deposition arrangement according to claim 3, wherein the actuator is connected to an exterior surface of a housing of the distribution assembly.

11. The material deposition arrangement according to claim 1, wherein the at least one material deposition source comprises a first deposition source, a second deposition source, and a third deposition source.

12. A material deposition arrangement for depositing a material on a substrate in a vacuum chamber, comprising:
a first deposition source having a first crucible configured to evaporate a first material, a first distribution assembly configured for providing the first material that is evaporated to the substrate, and a first valve configured to control a flow of the first material that is evaporated from the first crucible to the first distribution assembly; and
a second deposition source having a second crucible configured to evaporate a second material, and a second distribution assembly configured for providing the second material that is evaporated to the substrate, and a second valve configured to control a flow of the second material that is evaporated from the second crucible to the second distribution assembly.

13. A vacuum deposition system, comprising:
a vacuum deposition chamber;
a material deposition arrangement comprising a crucible, a distribution assembly connected to the crucible, and a valve configured to control a flow of evaporated material from the crucible to the distribution assembly in the vacuum deposition chamber; and
a substrate support configured for supporting a substrate during material deposition.

14. A method for operating a material deposition arrangement configured for depositing a material on a substrate in a vacuum deposition chamber, the method comprising:
evaporating a material to be deposited in a crucible connected to a distribution assembly; and
providing the material that is evaporated from the crucible to the distribution assembly, wherein providing the material that is evaporated from the crucible to the distribution assembly comprises controlling a flow of the material that is evaporated from the crucible to the at least one distribution assembly.

15. The method according to claim 14, wherein the method further comprises employing a material deposition arrangement for depositing a material on a substrate in a vacuum deposition chamber, comprising at least one material deposition source having:
a crucible configured to evaporate the material; and
a distribution assembly connected to the crucible, wherein the distribution assembly is configured for providing the material that is evaporated to the substrate; and
a valve configured to control a flow of the material that is evaporated from the crucible to the distribution assembly.

16. The material deposition arrangement according to claim 4, wherein the valve comprises a bellow configured to prevent evaporated material from entering the actuator arrangement.

17. The material deposition arrangement according to claim 4, wherein the movable element is coupled to the actuator via a coupling arrangement comprising a thermal insulation element.

18. The material deposition arrangement according to claim 5, wherein the movable element is coupled to the actuator via a coupling arrangement comprising a thermal insulation element.

19. The material deposition arrangement according to claim 10, wherein the distribution assembly comprises a distribution pipe with one or more outlets provided along the length of the distribution pipe.

20. The material deposition arrangement according to claim 10, wherein the at least one material deposition source comprises a first deposition source, a second deposition source, and a third deposition source.
